(19) United States
(12) Patent Application Publication
(10) Pub. No.: US 2015/0228895 A1
(43) Pub. Date: Aug. 13, 2015

(54) RESISTIVE RANDOM ACCESS MEMORY

(71) Applicant: Powerchip Technology Corporation, Hsinchu (TW)

(72) Inventors: Ching-Hua Chen, Hsinchu City (TW); Chan-Ching Lin, Hsinchu City (TW)

(73) Assignee: Powerchip Technology Corporation, Hsinchu (TW)

(21) Appl. No.: 14/267,935

(22) Filed: May 2, 2014

(30) Foreign Application Priority Data
Feb. 11, 2014 (TW) 103104419

(51) Int. Cl. H01L 45/00

(52) U.S. Cl. CPC H01L 45/145; H01L 45/1253; H01L 45/08

(57) ABSTRACT

A resistive random access memory including a first electrode, a dielectric layer, at least a first nanostructure and a second electrode is provided. The dielectric layer is disposed on the first electrode. The first nanostructure is disposed between the first electrode and the dielectric layer and includes a plurality of first cluster-type-type metal nanoparticles and a plurality of first covering-type metal nanoparticles. The first cluster-type-type metal nanoparticles are disposed on the first electrode. The first covering-type metal nanoparticles covers the first cluster-type-type metal nanoparticles, wherein a diffusion coefficient of the first cluster-type-type metal nanoparticles is larger than a diffusion coefficient of the first covering-type metal nanoparticles. The second electrode is disposed on the dielectric layer.

### CROSS-REFERENCE TO RELATED APPLICATION

This application claims the priority benefit of Taiwan application serial no. 103104419, filed on Feb. 11, 2014. The entirety of the above-mentioned patent application is hereby incorporated by reference herein and made a part of this specification.

### BACKGROUND OF THE INVENTION

1. Field of the Invention

The present invention generally relates to a memory, and more particularly to a resistive random access memory.

2. Description of Related Art

In recent years, along with the robust advancement of various types of electronic products and the increasing demands on functionality, the global market demand for memory rapidly expands; more particularly, the rapid development of non-volatile memory (NVM) draws the most attention. To cater these changes in the industry, every factories and research institutes around the world have been actively developing technologies on the next generation memory. Among the various potential technologies, the resistive random access memory (RRAM) possesses the characteristics of a simple structure, low write-in operation voltage, high speed operation, and non-volatile. Accordingly, the resistive random access memory has a competitive edge with respect to other non-volatile memories.

However, when the part of the electrode of a resistive random access memory that undergoes a redox reaction is completely oxidized, the resistive random access memory can no longer be used. Hence, to elevate the endurance of the resistive random access memory is an issue that is being actively pursued in the industry.

### SUMMARY OF THE INVENTION

The application is directed to a resistive random access memory that has better endurance.

An exemplary embodiment of the application provides a resistive random access memory that includes a first electrode, a dielectric layer, at least a first nanostructure and a second electrode. The dielectric layer is disposed on the first electrode. The first nanostructure is disposed between the first electrode and the dielectric layer, and the first nanostructure includes a plurality of first cluster-type metal nanoparticles and a plurality of first covering-type metal nanoparticles. The first cluster-type metal nanoparticles are disposed on the first electrode. The first covering-type metal nanoparticles cover the first cluster-type metal nanoparticles, wherein the diffusion coefficient of the first cluster-type metal nanoparticles is greater than the diffusion coefficient of the first covering-type metal nanoparticles. The second electrode is disposed on the dielectric layer.

According to the above exemplary embodiment of the resistive random access memory of the application, the material of the first electrode includes a transition metal or a nitride thereof.

According to the above exemplary embodiment of the resistive random access memory of the application, the first electrode is more easily oxidized than the second electrode.

According to the above exemplary embodiment of the resistive random access memory of the application, the material of the dielectric layer includes a high dielectric constant material.

According to the above exemplary embodiment of the resistive random access memory of the application, the first cluster-type metal nanoparticles and the first electrode includes the same metal element.

According to the above exemplary embodiment of the resistive random access memory of the application, the first cluster-type metal nanoparticles are oxidizable.

According to the above exemplary embodiment of the resistive random access memory of the application, the materials of the first cluster-type metal nanoparticles and the first covering-type metal nanoparticles respectively may include a transition metal.

According to the above exemplary embodiment of the resistive random access memory of the application, the potential of the first covering-type metal nanoparticles is higher than the potential of the first cluster-type metal nanoparticles.

According to the above exemplary embodiment of the resistive random access memory of the application, the diffusion coefficient of the first covering-type metal nanoparticles is greater than the diffusion coefficient of the material of the dielectric layer.

According to the above exemplary embodiment of the resistive random access memory of the application, the material of the first covering-type metal nanoparticles includes at least one type of metal.

According to the above exemplary embodiment of the resistive random access memory of the application, the material of the second electrode includes a transition metal or a nitride thereof.

According to the above exemplary embodiment of the resistive random access memory of the application, the resistive random access memory further includes an exothermic electrode, and the first electrode is disposed on the first exothermic electrode.

According to the above exemplary embodiment of the resistive random access memory of the application, the resistive random access memory further includes at least a second nanostructure, disposed between the second electrode and the dielectric layer, and the second nanostructure includes a plurality of second cluster-type metal nanoparticles and a plurality of second covering-type metal nanoparticles. The second cluster-type nanoparticles are disposed on the second electrode. The second covering-type metal nanoparticles cover the second cluster-type metal nanoparticles, and the diffusion coefficient of the second cluster-type metal nanoparticles is greater than the diffusion coefficient of the second covering-type metal nanoparticles.

According to the above exemplary embodiment of the resistive random access memory of the application, the second cluster-type metal nanoparticles and the second electrode include the same type of metal element.

According to the above exemplary embodiment of the resistive random access memory of the application, the second cluster-type metal nanoparticles are oxidizable.

According to the above exemplary embodiment of the resistive random access memory of the application, the material of the second cluster-type metal nanoparticles and the material of the second covering-type metal nanoparticles respectively may include a transition metal.

According to the above exemplary embodiment of the resistive random access memory of the application, the potential of the second covering-type metal nanoparticles is higher than the potential of the second cluster-type metal nanoparticles, for example.

According to the above exemplary embodiment of the resistive random access memory of the application, the diffusion coefficient of the second covering-type metal nanoparticles is greater than the diffusion coefficient of the dielectric layer.

According to the above exemplary embodiment of the resistive random access memory of the application, the material of the second covering-type metal nanoparticles includes at least one type of metal.

According to the above exemplary embodiment of the resistive random access memory of the application, the above resistive random access memory further includes a second exothermic electrode disposed on the second electrode.

Based on the above, because the resistive random access memory provided by the application includes the first nanostructure, and during the operation of the resistive random access memory, the cluster-type metal nanoparticles in the first nanostructure may serve as the redox materials, the endurance of the resistive random access memory may be enhanced.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a resistive random access memory of an exemplary embodiment of the application.

FIG. 2 is a schematic view depicting the operation of the resistive random access memory in FIG. 1.

FIG. 3 is a schematic view of a resistive random access memory of another exemplary embodiment of the application.

### DESCRIPTION OF THE EMBODIMENTS

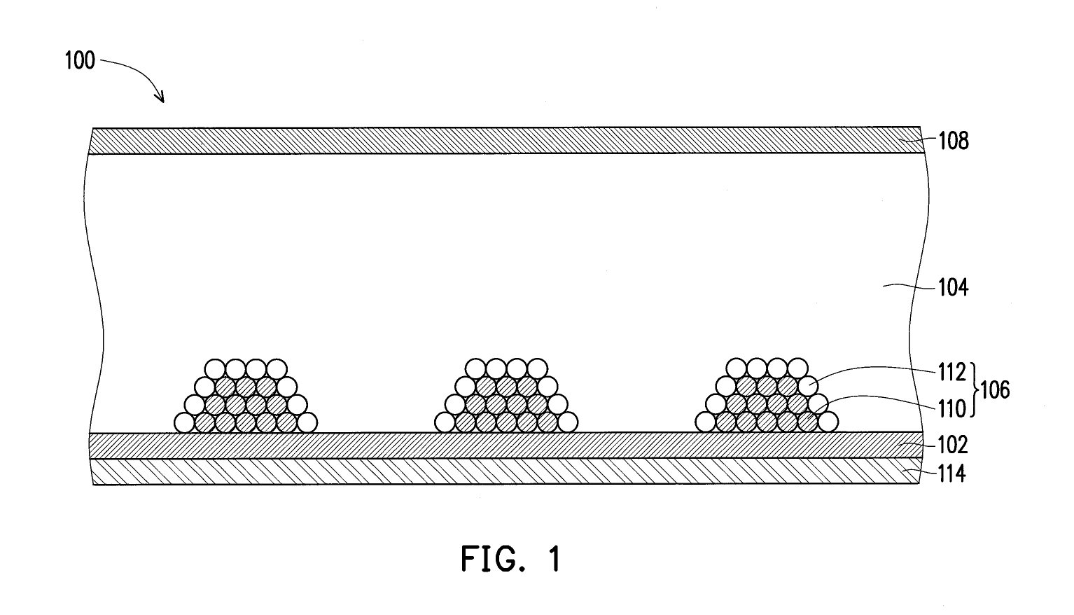

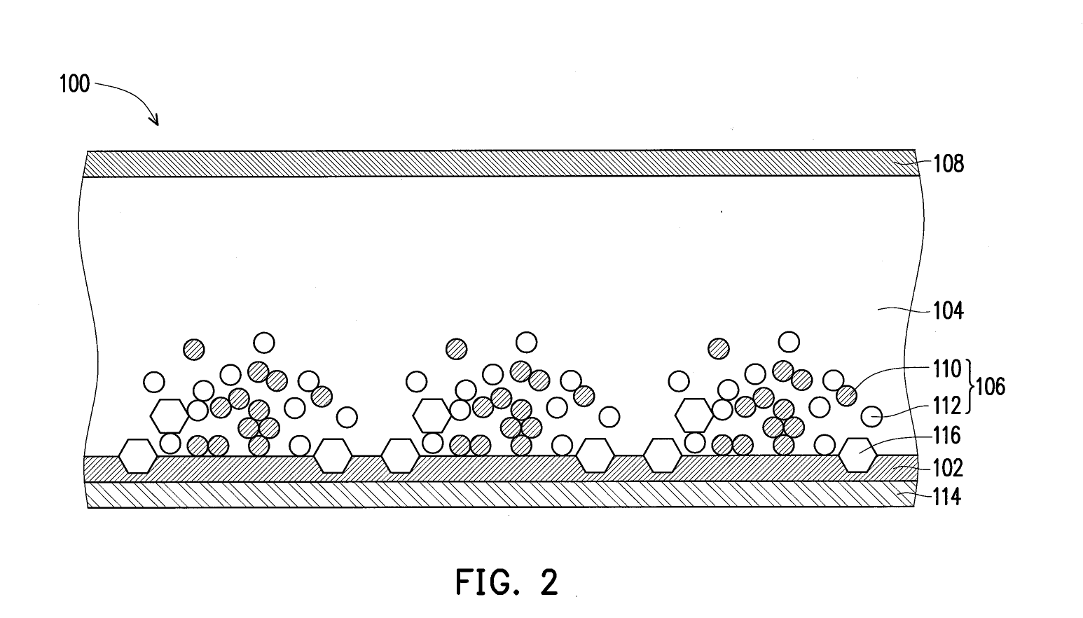

FIG. 1 is a schematic view of a resistive random access memory of an exemplary embodiment of the application. FIG. 2 is a schematic view depicting the operation of the resistive random access memory in FIG. 1.

Referring to FIG. 1, the resistive random access memory 100 includes an electrode 102, a dielectric layer 104, at least a nanostructure 106 and an electrode 108. The material of the electrode 102 includes a transition metal or a nitride thereof, such as Zr, Al, Ta, Hf, Ti, Cu, TiN or TaN. The electrode 102 is formed by, for example, a physical vapour deposition method, such as sputtering.

The dielectric layer 104 is disposed on the electrode 102. The material of dielectric layer 104 is, for example, a high dielectric constant material, such as metal oxide including, but not limited to, HfO₂, Al₂O₃, Ta₂O₅, ZrO₂, TiO₂, Cu₂O or CuO. In this exemplary embodiment, the material of the dielectric layer 104 is exemplified by HfO₂, but it should be understood that the above embodiment is presented by way of example and not by way of limitation. The dielectric layer 104 is formed by, for example, atomic layer deposition (ALD) or chemical vapour deposition (CVD).

The nanostructure 106 is disposed between the electrode 102 and the dielectric layer 104 and the nanostructure 106 includes a plurality of cluster-type metal nanoparticles 110 and a plurality of covering-type metal nanoparticles 112. The nanostructure 106, for example, is disposed on the electrode 102 and exposes a part of the electrode 102. The nanostructure 106 is formed by, for example, a spin-coating method. Although the disclosure herein refers a plurality of nanostructures 106, it should be understood by a person of ordinary skill practicing this application that the resistive random access memory 100 including at least one nanostructure 106 falls within the scope of this application.

The cluster-type metal nanoparticles 110 are disposed on the electrode 102 and form a cluster structure on the electrode 102. The cluster-type metal nanoparticles 110 are oxidizable. The material of the cluster-type metal nanoparticles 110 may include a transition metal, such as Zr, Al, Ta, Hf, Ti or Cu. The cluster-type metal nanoparticles 110 and the electrode 102 may have the same metal element(s). In this exemplary embodiment, the materials of the cluster-type metal nanoparticles 110 and the electrode 102 are both Zr. That is, the material of the cluster-type metal nanoparticles 110 and the material of the electrode 102 have the same metal element; however, the application is not limited hereby. The average particle size of the cluster-type metal nanoparticles 110 is, for example, 3 nm to 300 nm.

The covering-type metal nanoparticles 112 cover the plurality of cluster-type metal nanoparticles 110, wherein the diffusion coefficient of the cluster-type metal nanoparticles 110 is greater than that of the covering-type metal nanoparticles 112. The diffusion coefficient of the covering-type metal nanoparticles 112 is greater than the diffusion coefficient of the material of the dielectric layer 104. The material of the covering-type metal nanoparticles 112 includes a transition metal, such as Pt, Zr, Al, Ta, Hf, Ti or Cu. The potential of covering-type metal nanoparticles 112 is higher than the potential of the cluster-type metal nanoparticles 110, and it is based on this potential variance between the cluster-type metal nanoparticles 110 and the covering-type metal nanoparticles 112 for the covering-type metal nanoparticles 112 to cover the cluster-type metal nanoparticles 110. For example, the potential of the covering-type metal nanoparticles 112 whose material is platinum (Pt) is higher than that of the cluster-type metal nanoparticles 110 whose material is zirconium (Zr). It should be understood that the above embodiment is presented by way of example and not by way of limitation.

Moreover, the material of the covering-type metal nanoparticles 112 can be one type of metal or at least two types of metal. Although the disclosure herein is exemplified by the material of the covering-type metal nanoparticles 112 being one type of metal (such as Pt), it is to be understood that, in other exemplary embodiments, the material of the covering-type metal nanoparticles 112 may include two or more types of metal. The average particle size of the covering-type metal nanoparticles 112 is, for example, 3 nm to 300 nm.

The electrode 108 is disposed on the dielectric layer 104. The material of the electrode 108 is, for example, a transition metal or a nitride thereof, such as Pt, Zr, Al, Ta, Hf, Ti, Cu, TiN or TaN. The electrode 108 is formed by, for example, physical vapour deposition, such as sputtering. The electrode 102 is more easily being oxidized than the electrode 108, for example. For example, the electrode 102 whose material is Zr is more easily oxidized than the electrode 108 whose material is Pt. It should be understood that these embodiments are presented by way of example and not by way of limitation.

The resistive random access memory 100 further includes an exothermic electrode 114, and the electrode 102 may be disposed on the exothermic electrode 114. The material of the exothermic electrode 114 is, for example, an exothermic metal material, such as TiSiN or TaSiN. The exothermic electrode 114 is formed by chemical vapour deposition, for example.

Referring concurrently to FIGS. 1 and 2, during the operation of the resistive random access memory 100, a redox reaction is undergone at the interface of the electrode 102 and the dielectric layer 104 to generate phonons, and the vibration of the phonons induces joule heating. When the thermal energy is transmitted to the cluster-type metal nanoparticles 110 and the covering-type metal nanoparticles 112, the cluster-type metal nanoparticles and the covering-type metal nanoparticles 112 undergo diffusions due to the kirkendall effect. Alternatively speaking, the covering-type metal nanoparticles 112 (such as the Pt nanoparticles) and the cluster-type metal nanoparticles 110 (such as the Zr nanoparticles) having larger diffusion coefficients will diffuse to the dielectric layer 104 (such as HfO₂) having a smaller diffusion coefficient, so that the cluster-type metal nanoparticles 110 will diffuse from the nanostructure 106 into the dielectric layer 104.

Accordingly, during the operation of the resistive random access memory 100, in addition to having the electrode 102 to serve as a redox material, the cluster-type metal nanoparticles 110 may also serve as a redox material to elevate the endurance of the resistive random access memory. In this exemplary embodiment, the oxide material 116 generated during the operation of the resistive random access memory 100 is, for example, ZrO, but the invention is not limited thereto.

In addition, when the resistive random access memory 100 includes the exothermic electrode 114, the diffusion efficiencies of the cluster-type metal nanoparticles 110 and the covering-type metal nanoparticles 112 are enhanced since the transmission of thermal energy to the cluster-type metal nanoparticles 110 and the covering-type metal nanoparticles 112 is facilitated by the exothermic electrode 114.

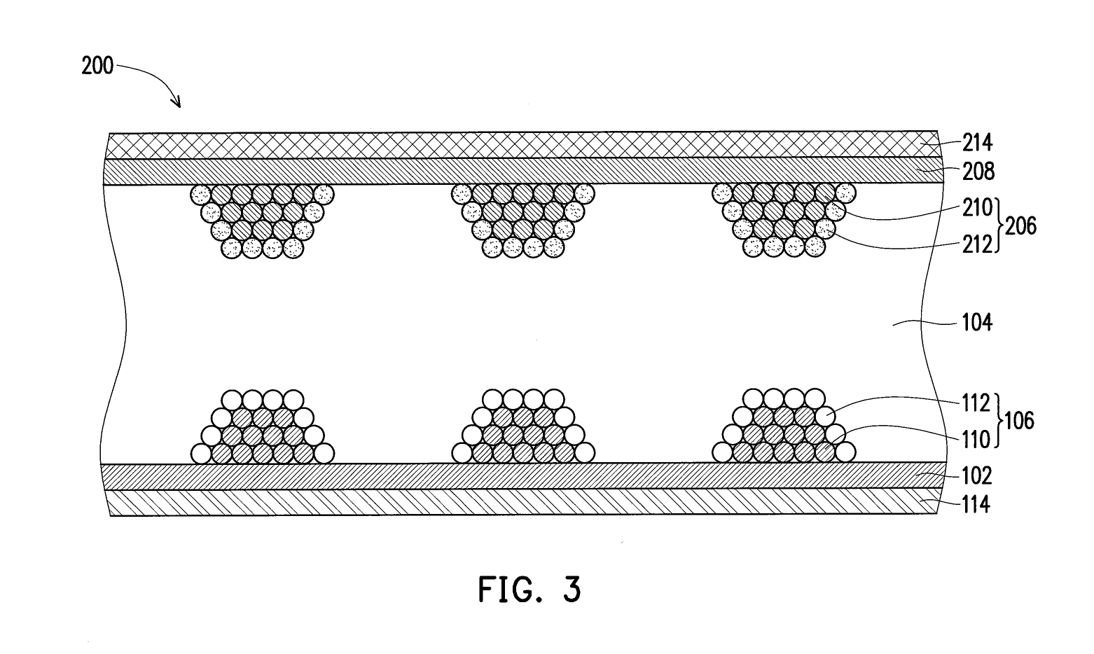

FIG. 3 is a schematic view of a resistive random access memory of another exemplary embodiment of the application.

Referring concurrently to FIGS. 1 and 3, the difference between the resistive random access memory 200 of FIG. 3 and the resistive random access memory 100 of FIG. 1 lies in that the resistive random access memory 200 further includes at least one nanostructure 206. Further, the material of the electrode 208 is different from the material of the electrode 108 in that the material of the electrode 208 is not platinum (Pt). Moreover, the resistive random access memory 200 further includes an exothermic electrode 214 disposed on the electrode 208. Other elements in FIG. 2 that are the same or similar to those in FIG. 1, the same reference numbers are used in the drawings and the disclosure, and the descriptions thereof are omitted herein.

The nanostructure 206 is disposed between the electrode 208 and the dielectric layer 104, and the nanostructure 206 includes a plurality of cluster-type metal nanoparticles 210 and a plurality of covering-type metal nanoparticles 212. The nanostructure 206, for example, is disposed on the electrode 208 and exposes a part of the electrode 208. The nanostructure 206 is formed by, for example, a spin-coating method. Although the disclosure herein refers a plurality of nanostructures 206, it should be understood by a person of ordinary skill practicing this application that the resistive random access memory 200 including at least one nanostructure 206 falls within the scope of this application.

The cluster-type metal nanoparticles 210 are disposed on the electrode 208 and may form the cluster structure on the electrode 208. The cluster-type metal nanoparticles 210 are oxidizable. The material of the cluster-type metal nanoparticles 210 may include a transition metal, such as Zr, Al, Ta, Hf, Ti or Cu. The cluster-type metal nanoparticles 210 and the electrode 208 may have the same metal element. In this exemplary embodiment, the materials of the cluster-type metal nanoparticles 210 and the electrode 208 are both Al. Therefore, the material of the cluster-type metal nanoparticles 210 and the material of the electrode 208 have the same metal element; however, the application is not limited hereby. The average particle size of the cluster-type metal nanoparticles 210 is, for example, 3 nm to 300 nm.

The covering-type metal nanoparticles 212 cover the plurality of cluster-type metal nanoparticles 210, wherein the diffusion coefficient of the cluster-type metal nanoparticles 210 is greater than that of the covering-type metal nanoparticles 212. The diffusion coefficient of the covering-type metal nanoparticles 212 is greater than the diffusion coefficient of the material of the dielectric layer 104. The material of the covering-type metal nanoparticles includes a transition metal, such as Pt, Zr, Al, Ta, Hf, Ti or Cu. The potential of the covering-type metal nanoparticles 212 is higher than the potential of the cluster-type metal nanoparticles 210, and it is based on this potential variance between the covering-type metal nanoparticles 212 and the cluster-type metal nanoparticles 210 for the covering-type metal nanoparticles 212 to cover the cluster-type metal nanoparticles 210. For example, the potential of the covering-type metal nanoparticles 212 whose material is platinum (Pt) is higher than that of the cluster-type metal nanoparticles 210 whose material is aluminium (Al). It should be understood that the above embodiment is presented by way of example and not by way of limitation.

Moreover, the material of the covering-type metal nanoparticles 212 can be one type of metal or at least two types of metal. Although the disclosure herein is exemplified by the material of the covering-type metal nanoparticles 212 being one type of metal (such as Pt), it is to be understood that, in other exemplary embodiments, the material of the covering-type metal nanoparticles 212 may include two or more types of metal. The average particle size of the covering-type metal nanoparticles 212 is, for example, 3 nm to 300 nm.

The material of the electrode 208 is, for example, a transition metal other than Pt, such as Zr, Al, Ta, Hf, Ti, or Cu. In this exemplary embodiment, the material of the electrode 208 is exemplified by aluminium (Al), but the invention is not limited thereto. The electrode 102 is more easily oxidized than the electrode 208, for example. For example, the electrode 102 whose material is Zr is more easily oxidized than the electrode 108 whose material is Al. It should be understood that these embodiments are presented by way of example and not by way of limitation.

Moreover, the material of the exothermic electrode 214 is, for example, an exothermic metal material, such as TiSiN or TaSiN. The exothermic electrode 214 is formed by chemical vapour deposition, for example.

Since the operational principle and mechanism of the nanostructure 206 are similar to those of the nanostructure 106 in the above-mentioned exemplary embodiment, during the operation of the resistive random access memory 200, aside from having the electrode 102 and the electrode 208 to serve as redox materials, the cluster-type metal nanoparticles 110 and the cluster-type metal nanoparticles 210 may also serve as the redox materials during the operation to enhance the endurance of the resistive random access memory 200.

Further, when the resistive random access memory 200 includes the exothermic electrode 114 and the exothermic electrode 214, the exothermic electrode 114 and the exothermic electrode 214 assist in transmitting the thermal energy to the cluster-type metal nanoparticles 110, 210 and the covering-type metal nanoparticles 112, 212 to increase the diffusion efficiency of the cluster-type metal nanoparticles 110, 210 and the covering-type metal nanoparticles 112, 212.

According to the exemplary embodiments of the disclosure, as long as the resistive random access memory includes the nanostructure between one electrode and the dielectric layer, the cluster-type metal nanoparticles in the nanostructure can serve as a redox material to increase the endurance of the resistive random access memory.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A resistive random access memory, comprising:
a first electrode;
a dielectric layer, disposed on the first electrode;
at least a first nanostructure, disposed between the first electrode and the electrode layer, and the first nanostructure comprising:
a plurality of first cluster-type metal nanoparticles, disposed on the first electrode; and
a plurality of first covering-type metal nanoparticles, covering the plurality of first cluster-type metal nanoparticles, wherein a diffusion coefficient of the plurality of first cluster-type metal nanoparticles is greater than a diffusion coefficient of the plurality of first covering-type metal nanoparticles; and
a second electrode disposed on the dielectric layer.

2. The resistive random access memory according to claim 1, wherein a material of the first electrode comprises a transition metal or a nitride thereof.

3. The resistive random access memory according to claim 1, wherein the first electrode is easier to be oxidized than the second electrode.

4. The resistive random access memory according to claim 1, wherein a material of the dielectric layer comprises a high dielectric constant material.

5. The resistive random access memory according to claim 1, wherein the plurality of first cluster-type metal nanoparticles and the first electrode comprise the same metal element.

6. The resistive random access memory according to claim 1, wherein the plurality of cluster-type metal nanoparticles are oxidizable.

7. The resistive random access memory according to claim 1, wherein a material of the plurality of first cluster-type nanoparticles and a material of the plurality of covering-type metal nanoparticles respectively comprises a transition metal.

8. The resistive random access memory according to claim 1, wherein a potential of the plurality of covering-type metal nanoparticles is higher than a potential of the plurality of cluster-type metal nanoparticles.

9. The resistive random access memory according to claim 1, wherein a diffusion coefficient of the plurality of covering-type metal nanoparticles is greater than a diffusion coefficient of a material of the dielectric layer.

10. The resistive random access memory of claim 1, wherein a material of the plurality of covering-type metal nanoparticles comprises at least one type of metal.

11. The resistive random access memory according to claim 1, wherein a material of the second electrode comprises a transition metal or a nitride thereof.

12. The resistive random access memory according to claim 1, further comprising a first exothermic electrode, and the first electrode is disposed on the first exothermic electrode.

13. The resistive random access memory according to claim 1, further comprising at least a second nanostructure, disposed between the second electrode and the dielectric layer, and the second nanostructure comprises:
a plurality of second cluster-type metal nanoparticles, disposed on the second electrode; and
a plurality of second covering-type metal nanoparticles, covering the plurality of second cluster-type metal nanoparticles, wherein a diffusion coefficient of the second cluster-type metal nanoparticles is greater than a diffusion coefficient of the second covering-type metal nanoparticles.

14. The resistive random access memory according to claim 13, wherein the plurality of second cluster-type metal nanoparticles and the second electrode comprise the same metal element.

15. The resistive random access memory according to claim 13, wherein the plurality of second cluster-type metal nanoparticles are oxidizable.

16. The resistive random access memory according to claim 13, wherein a material of the plurality of second cluster-type metal nanoparticles and a material of the plurality of second covering-type metal nanoparticles respectively comprises a transition metal.

17. The resistive random access memory according to claim 13, wherein a potential of the plurality of second covering-type metal nanoparticles is higher than a potential of the plurality of second cluster-type metal nanoparticles.

18. The resistive random access memory according to claim 13, wherein a diffusion coefficient of the plurality of second covering-type metal nanoparticles is greater than a diffusion coefficient of the dielectric layer.

19. The resistive random access memory according to claim 13, wherein a material of the plurality of second covering-type metal nanoparticles comprises at least one type of metal.

20. The resistive random access memory according to claim 1, further comprising a second exothermic electrode disposed on the second electrode.
